(19) United States
(12) Patent Application Publication
(10) Pub. No.: US 2015/0340445 A1
(43) Pub. Date: Nov. 26, 2015

(54) SUBSTRATE STRUCTURE AND SEMICONDUCTOR DEVICE ON THE SUBSTRATE STRUCTURE

(71) Applicant: SAMSUNG ELECTRONICS CO., LTD., Suwon-si (KR)

(72) Inventors: Joon-Young CHOI, Suwon-si (KR); Tae-Gon KIM, Seoul (KR); Hyun-Pil NOH, Seongnam-si (KR); Jae-Sik BAE, Osan-si (KR); Sam-Jong CHOI, Suwon-si (KR)

(21) Appl. No.: 14/645,888

(22) Filed: Mar. 12, 2015

(30) Foreign Application Priority Data
May 22, 2014 (KR) 10-2014-0061340

(51) Int. Cl. H01L 29/36; H01L 27/146

(52) U.S. Cl. CPC H01L 29/36; H01L 27/14612

(57) ABSTRACT

A substrate structure include a lower substrate doped with n-type impurities having a first impurity concentration, an epitaxial layer on the lower substrate, and a metallic-contaminant collection area spaced apart from the epitaxial layer in the lower substrate, the metallic-contaminant collection area doped with impurities having a second impurity concentration higher than the first impurity concentration, the metallic-contaminant collection area having lattice defects, and an upper surface of the metallic-contaminant collection area being spaced apart from a top surface of the lower substrate at a distance in a range of about 0.1 μm to about 3 μm.

### CROSS-REFERENCE TO RELATED APPLICATION

Korean Patent Application No. 10-2014-0061340, filed on May 22, 2014, in the Korean Intellectual Property Office, and entitled: “Substrate Structure and Semiconductor Device on the Substrate Structure,” is incorporated by reference herein in its entirety.

### BACKGROUND

1. Field

Embodiments relate to a substrate structure and a semiconductor device on the substrate structure.

2. Description of the Related Art

A silicon substrate may be used for fabrication of a semiconductor device. The purity of the silicon substrate may impact the performance of the semiconductor device manufactured thereon.

### SUMMARY

Embodiments are directed to a substrate structure, including a lower substrate doped with n-type impurities having a first impurity concentration, an epitaxial layer on the lower substrate, and a metallic-contaminant collection area spaced apart from the epitaxial layer in the lower substrate, the metallic-contaminant collection area doped with impurities having a second impurity concentration higher than the first impurity concentration, the metallic-contaminant collection area having lattice defects, and an upper surface of the metallic-contaminant collection area being spaced apart from a top surface of the lower substrate at a distance in a range of about 0.1 μm to about 3 μm.

The impurities doped into the metallic-contaminant collection area may include n-type impurities or p-type impurities.

A thickness of the metallic-contaminant collection area in a first direction substantially vertical to the top surface of the lower substrate may be in a range of about 0.5 μm to about 5 μm.

The second impurity concentration may be in a range of about 1E12 atoms/cm² to 1E16 atoms/cm².

The epitaxial layer may be doped with n-type impurities having a third impurity concentration lower than the second impurity concentration.

The lower substrate may include oxygen precipitates therein under the metallic-contaminant collection area.

The lower substrate may be doped with nitrogen or carbon under the metallic-contaminant collection area.

Embodiments are also directed to a semiconductor device, including a lower substrate doped with n-type impurities having a first impurity concentration, an epitaxial layer on the lower substrate, the epitaxial layer doped with n-type impurities having a second impurity concentration, a metallic-contaminant collection area spaced apart from the epitaxial layer in the lower substrate, the metallic-contaminant collection area doped with impurities having a second impurity concentration higher than the first and second impurity concentrations, the metallic-contaminant collection area having lattice defects, and an upper surface of the metallic-contaminant collection area being spaced apart from a top surface of the lower substrate at a distance in a range of about 0.1 μm to 3 μm, and a unit cell formed on the epitaxial layer, a portion of the epitaxial layer serving as an active region for forming the unit cell.

The unit cell may be a unit cell of an image sensor. The unit cell of the image sensor may include a photodiode in the epitaxial layer, the photodiode contacting the upper surface of the metallic-contaminant collection area.

The photodiode, the metallic-contaminant collection area and a portion of the lower substrate under the metallic-contaminant collection area may have a junction structure of p-type impurities, n-type impurities, p-type impurities, and n-type impurities in a first direction substantially vertical to a top surface of the lower substrate.

The unit cell may be a unit cell of a power semiconductor device, and the unit cell of the power semiconductor device may include a power MOS transistor.

The second impurity concentration may be in a range of about 1E12 atoms/cm² to about 1E16 atoms/cm².

The impurities doped into the metallic-contaminant collection area may include n-type impurities or p-type impurities.

A polarity of the impurities doped into the metallic-contaminant collection area may be opposite to that of metallic contaminants collected from the epitaxial layer.

A thickness of the metallic-contaminant collection area in a first direction substantially vertical to a top surface of the lower substrate may be in a range of about 0.5 μm to about 5 μm.

Embodiments are also directed to a semiconductor device, including a single crystalline body region doped with a first type impurity at a first concentration, a first region, the first region being in the body region and doped with one or more of nitrogen or carbon, a second region in the body region, the second region being doped with first type or second type impurities at a second concentration higher than the first concentration, and an epitaxial region on the body region, the second region being spaced apart from the epitaxial region and below the epitaxial region such that the second region is covered by the epitaxial region but does not contact the epitaxial region.

The first type impurity may be n-type, the second type impurity may be p-type, and the second region may be doped with the first type impurities.

The first type impurity may be n-type, the second type impurity may be p-type, and the second region may be doped with the second type impurities.

The first type impurity may be n-type, the second type impurity may be p-type, and the epitaxial region may be doped with the first type impurities at a third concentration that is lower than the second concentration.

The body region, the first region, the second region, and the epitaxial region may all be laterally continuous and laterally coextensive, and an active region and one or more impurity wells may be on the epitaxial region on an opposite side of the epitaxial region from the second region.

### BRIEF DESCRIPTION OF THE DRAWINGS

Features will become apparent to those of skill in the art by describing in detail example embodiments with reference to the attached drawings in which:

FIG. 1 illustrates a cross-sectional view of a substrate structure for fabrication of devices in accordance with example embodiments;

FIGS. 2 to 4 illustrate cross-sectional views of stages of a method of forming the substrate structure for fabrication of devices of FIG. 1;

FIG. 5 illustrates a cross-sectional view of a substrate structure for fabrication of devices in accordance with example embodiments;

FIG. 6 illustrates a cross-sectional view of a CMOS image sensor in accordance with example embodiments;

FIG. 7 illustrates an energy band diagram of portions of cut along a line A-A′ of FIG. 6;

FIGS. 8 to 13 illustrate cross-sectional views of stages of a method of forming the CMOS image sensor of FIG. 6;

FIG. 14 illustrates a cross-sectional view of a CMOS image sensor in accordance with example embodiments;

FIG. 15 illustrates a cross-sectional view of a CMOS image sensor in accordance with example embodiments;

FIGS. 16 to 21 illustrate cross-sectional views of stages of a method of forming the substrate structure for fabrication of devices of FIG. 15;

FIG. 22 illustrates a cross-sectional view of a power semiconductor device in accordance with example embodiments;

FIGS. 23 to 25 illustrate cross-sectional views of stages of a method of forming the power semiconductor device of FIG. 22;

FIG. 26 illustrates a cross-sectional view of a substrate structure for fabrication of devices in accordance with example embodiments;

FIG. 27 illustrates a cross-sectional view of a substrate structure for fabrication of devices in accordance with example embodiments;

FIG. 28 illustrates a cross-sectional view of a substrate structure for fabrication of devices in accordance with example embodiments;

FIG. 29 illustrates a graph of components analysis of an example for gettering of metallic contaminants using a SIMS (secondary ion mass spectroscopy).

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey example implementations to those skilled in the art.

In the drawing figures, the dimensions of layers and regions may be exaggerated for clarity of illustration. Like reference numerals refer to like elements throughout.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items.

It will be understood that, although the terms first, second, third, fourth etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concept.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present inventive concept. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

FIG. 1 is a cross-sectional view illustrating a substrate structure for fabrication of a semiconductor device in accordance with example embodiments.

Referring to FIG. 1, the substrate structure may have a lower substrate 10 that may include single crystalline silicon doped with n-type impurities. An epitaxial layer 20 doped with n-type impurities may be formed on the lower substrate 10. The epitaxial layer 20 may serve as a region for forming a semiconductor device. The lower substrate 10 may include oxygen precipitates 12 therein. The lower substrate 10 may include a bulk area 13. The lower substrate 10 may include a metallic-contaminant collection area 14 and an upper area 16 on the metallic-contaminant collection area 14

The lower substrate 10 may serve as a starting material of the substrate structure for fabrication of the semiconductor device. The lower substrate 10 may be lightly doped with n-type impurities, and thus the lower substrate 10 may be an n− single crystalline silicon substrate. An entire region of the lower substrate 10 may have a first impurity concentration. For example, the first impurity concentration may be lower than about 1E13 atoms/cm². The n-type impurities may include, e.g., phosphorus (P), arsenic (As), antimony (Sb), etc.

The lower substrate 10 may include oxygen precipitates 12 therein. The oxygen precipitates 12 may be spaced apart from a top surface of the lower substrate 10. Thus, defects due to the oxygen precipitates 12 may not affect the epitaxial layer 20. When uppermost ones of the oxygen precipitates 12 in the lower substrate 10 are spaced apart from the top surface of the lower substrate 10 in a first direction (the first direction may be substantially vertical to the top surface of the lower substrate 10) at a distance less than about 0.1 μm, the defects due to the oxygen precipitates 12 may affect the epitaxial layer 20. When the uppermost ones of the oxygen precipitates 12 in the lower substrate 10 are spaced apart from the top surface of the lower substrate 10 in the first direction at a distance more than about 5 the lower substrate 10 may not sufficiently collect or getter metallic contaminants. Thus, the uppermost ones of the oxygen precipitates 12 may be disposed in the lower substrate 10 at a distance in a range of about 0.1 μm to about 5 μm from the top surface of the lower substrate 10, and the oxygen precipitates 12 may be disposed, e.g., uniformly, throughout in the lower substrate 10 to the bottom of the lower substrate 10.

The lower substrate 10 may be doped with carbon and/or nitrogen. The carbon or nitrogen may be doped to form the oxygen precipitates 12. Thus, an uppermost one of the carbon or nitrogen may be disposed at a distance in a range of about 0.1 μm to about 5 μm from the top surface of the lower substrate 10, and the carbon or nitrogen may be disposed throughout in the lower substrate 10 to the bottom of the lower substrate 10.

As described above, the lower substrate 10 may be doped with n-type impurities. A size of n-type impurities, e.g., arsenic may be greater than that of p-type impurities, e.g., boron. Thus, when the lower substrate 10 is doped with n-type impurities, a vacancy generated by doping n-type impurities may have a small size. The oxygen precipitates 12 may be formed in the vacancy, and thus a very small amount of oxygen precipitate may be formed in the lower substrate 10 doped with n-type impurities when compared to that formed in a lower substrate doped with p-type impurities. Thus, the lower substrate 10 doped with n-type impurities may be doped with carbon or nitrogen so as to generate a vacancy for forming oxygen precipitates.

A crystal lattice of silicon at a portion of the lower substrate 10, in which the oxygen precipitates 12 are formed, may be deformed. Thus, metallic contaminants may be collected or gettered by a stress of the portion of the lower substrate 10 in which the oxygen precipitates 12 are formed.

The lower substrate 10 may include the metallic-contaminant collection area 14 and the bulk area 13 under the metallic-contaminant collection area 14. The metallic contaminants may be collected or gettered at the portion of the bulk area 13 in which the oxygen precipitates 12 are formed.

The metallic-contaminant collection area 14 may be doped with impurities (e.g., charged impurities) in the lower substrate 10. The impurities may be n-type impurities or p-type impurities. Thus, the metallic-contaminant collection area 14 may be doped with n-type impurities or p-type impurities to have a second impurity concentration. A crystal lattice of the metallic-contaminant collection area 14 may be dislocated, so that lattice defects or crystal defects may be generated in the metallic-contaminant collection area 14. The metallic-contaminant collection area 14 may be highly doped with impurities, and may have defects therein. The second impurity concentration may be higher than the first impurity concentration. The metallic-contaminant collection area 14 may be a p+ (p plus) doping region or an n+ (n plus) doping region.

The metallic-contaminant collection area 14 may collect or getter metallic contaminants from a portion in which a semiconductor device may be formed, and may collect a large amount of metallic contaminant. Thus, the epitaxial layer 20 may have a very small amount of metallic contaminant or no metallic contaminant. The metallic contaminants collected or gettered in the metallic-contaminant collection area 14 may not affect the semiconductor device formed on the epitaxial layer 20.

The metallic-contaminant collection area 14 may be formed to be adjacent to the top surface of the lower substrate 10 so as to effectively collect or getter the metallic contaminants at a portion in which the semiconductor device may be formed. However, when the metallic-contaminant collection area 14 directly contacts a lower surface of the epitaxial layer 20, the defects of the metallic-contaminant collection area 14 may affect the epitaxial layer 20. Thus, the defects of the metallic-contaminant collection area 14 may be transferred to the epitaxial layer 20 so that the epitaxial layer 20 may also have defects. Thus, the metallic-contaminant collection area 14 may be spaced apart from the top surface of the lower substrate 10. Therefore, the lower substrate 10 may include the metallic-contaminant collection area 14 and an upper area 16 on the metallic-contaminant collection area 14. The upper area 16 may have neither crystal defects nor oxygen precipitates, and may be doped with n-type impurities. Thus, the metallic-contaminant collection area 14 may be formed between the upper area 16 and the bulk area 13 in the lower substrate 10, and the upper area 16 and the bulk area 13 may be separated by the metallic-contaminant collection area 14.

When the metallic-contaminant collection area 14 is spaced apart from the top surface of the lower substrate 10 in the first direction at a distance more than about 0.1 μm, the defects of the metallic-contaminant collection area 14 may affect the epitaxial layer 20. When the metallic-contaminant collection area 14 is spaced apart from the top surface of the lower substrate 10 in the first direction at a distance less than about 3 μm, the metallic-contaminant collection area 14 may not sufficiently collect or getter metallic contaminants from the epitaxial layer 20. Thus, an upper surface of the metallic-contaminant collection area 14 may be disposed at a distance in a range of about 0.1 μm to about 3 μm from the top surface of the lower substrate 10.

The metallic-contaminant collection area 14 may have a given thickness in the first direction. When the thickness of the metallic-contaminant collection area 14 in the first direction is less than about 0.5 μm, a size of the metallic-contaminant collection area 14 may be too small to collect metallic contaminants. When the thickness of the metallic-contaminant collection area 14 in the first direction is more than about 5 μm, the defects of the metallic-contaminant collection area 14 may increase so as to affect the epitaxial layer 20. Thus, the thickness of the metallic-contaminant collection area 14 in the first direction may be in a range of about 0.5 μm to about 5 μm.

Impurities doped into the metallic-contaminant collection area 14 may collect or getter metallic contaminants by an electrical force of attraction. Also, a stress may be generated at a portion of the metallic-contaminant collection area 14 having defects due to the doped impurities, and the metallic contaminants may be collected or gettered by the stress.

When the second concentration of the metallic-contaminant collection area 14 is less than about 1E12 atoms/cm², the metallic contaminants may not be sufficiently collected or gettered. When the second concentration of the metallic-contaminant collection area 14 is more than about 1E16 atoms/cm², the metallic-contaminant collection area 14 may have a large amount of defects that may negatively affect the epitaxial layer 20 for forming the semiconductor device. Thus, the second concentration of the metallic-contaminant collection area 14 may be in a range of about 1E12 atoms/cm² to about 1E16 atoms/cm². For example, the second concentration of the metallic-contaminant collection area 14 may be in a range of about 1E13 atoms/cm² to about 1E15 atoms/cm². The metallic-contaminant collection area 14 may include p-type impurities, e.g., boron (B), indium (In), gallium (Ga), etc., or n-type impurities, e.g., arsenic, phosphorus, antimony, etc.

As described above, a relaxation gettering due to the defects and a segregation gettering due to the electrical force of attraction may be generated together in the metallic-contaminant collection area 14 so that the metallic contaminants at a region for forming the semiconductor device may be effectively collected or gettered in the metallic-contaminant collection area 14.

According to a conductivity type of a metal or metallic contaminants included in the semiconductor device formed on the epitaxial layer 20, the metallic-contaminant collection area 14 may be doped with one of p-type impurities and n-type impurities.

When metallic contaminants to be collected have a positive charge, the metallic-contaminant collection area 14 may be doped with the p-type impurities to have a negative charge or a negative ion. When metallic contaminants to be collected have a negative charge, the metallic-contaminant collection area 14 may be doped with the n-type impurities to have a positive charge or positive ion. In an example embodiment, most of the metallic contaminants included in the semiconductor device may have a positive charge, and thus the metallic-contaminant collection area 14 may be doped with the p-type impurities to have a negative charge or a negative ion. For example, the metallic-contaminant collection area 14 may be doped with the boron to have an impurity concentration of about 1E12 atoms/cm² to about 1E16 atoms/cm².

As the relaxation gettering and segregation gettering may be generated together in the metallic-contaminant collection area 14, metallic contaminants having various rates of diffusion and solution may be effectively collected or gettered in the metallic-contaminant collection area 14. For example, metallic contaminants having a relatively low rate of diffusion, such as titanium, and metallic contaminants having a relatively high rate of diffusion, such as copper, may be together collected or gettered in the metallic-contaminant collection area 14.

The epitaxial layer 20 on the lower substrate 10 may have a suitable thickness for forming the semiconductor device. The epitaxial layer 20 may be doped with impurities, and, according to the semiconductor device formed on the epitaxial layer 20, the conductivity type of the impurities may be determined. Thus, the epitaxial layer 20 may be doped with n-type impurities or p-type impurities to have a third impurity concentration. The third impurity concentration may be lower than the second concentration. For example, the epitaxial layer 20 may be lightly doped with n-type impurities, and thus may be an n− (n minus) single crystalline silicon layer.

As described above, the substrate structure for fabrication of a semiconductor device may have the n-type lower substrate 10 and the epitaxial layer 20 on the n-type lower substrate 10. The metallic contaminants may be effectively collected or gettered in the metallic-contaminant collection area 14 and the portion of the lower substrate 10 in which the oxygen precipitates 12 are formed. Thus, the metallic contaminants of the epitaxial layer 20 may decrease, so that a failure of the semiconductor device formed on the epitaxial layer 20 may be decreased.

In example embodiments, the substrate structure for fabrication of a semiconductor device may not be significantly affected by metallic contaminants. Thus, the substrate structure for fabrication of a semiconductor device may be used for fabricating various types of semiconductor devices. For example, the substrate structure for fabrication of a semiconductor device may be used for fabricating a semiconductor device that may have a good performance on an n-type lower substrate.

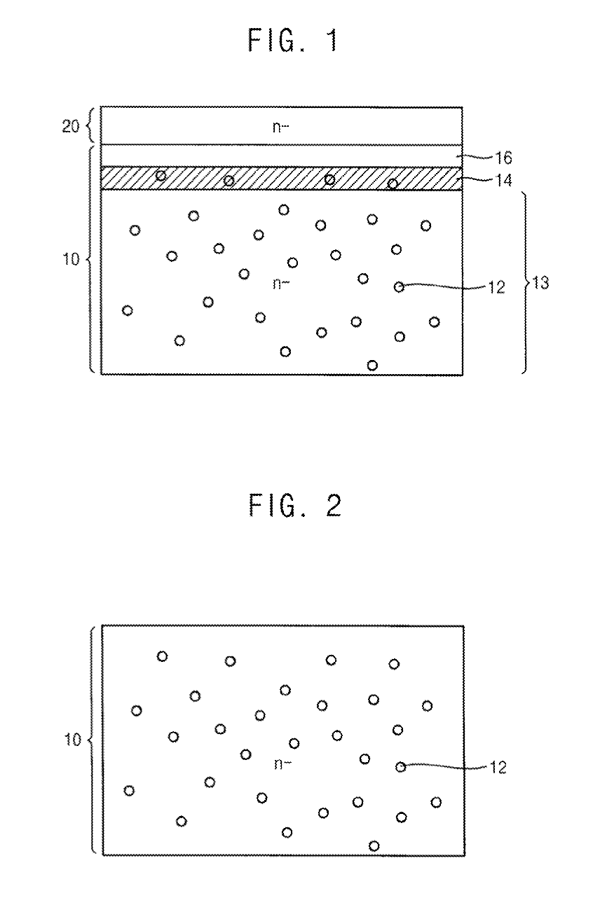

FIGS. 2 to 4 are cross-sectional views illustrating stages of a method of forming the substrate structure for fabrication of a semiconductor device of FIG. 1.

Referring to FIG. 2, a lower substrate 10 including single crystalline silicon may be doped with first impurities, e.g., n-type impurities. In an implementation, the impurities may be uniformly doped throughout the lower substrate 10. The lower substrate 10 may be doped with carbon or nitrogen to form oxygen precipitates 12 for collecting or gettering metallic contaminants. Thus, the lower substrate 10 may be an n− substrate doped with n-type impurities to have a first impurity concentration. For example, the first impurity concentration may be equal to or less than about 1E13 atoms/cm².

In example embodiments, the lower substrate 10 may be formed by a Czochralski process. In the Czochralski process, a molten silicon seed crystal within a quartz crucible may be slowly pulled upward to form a single crystal ingot, and the single crystal ingot may be cut to form a base substrate. The molten silicon seed crystal within the quartz crucible may be doped with n-type impurities. The n-type impurities may include, e.g., arsenic, phosphorus, antimony, etc. Also, the molten silicon seed crystal within the quartz crucible may be doped with carbon or nitrogen to form the oxygen precipitates. The base substrate may be cured at a high temperature and, e.g., an HCl treatment may be performed thereon to form the lower substrate 10 in which the oxygen precipitates 12 at a top surface of the base substrate may be removed. Thus, the oxygen precipitates 12 may be uniformly formed from an upper portion of the lower substrate 10 at a distance of about 0.1 μm to about 5 μm from the top surface of the lower substrate 10 to the bottom of the lower substrate 10.

In another implementation, the base substrate formed by the Czochralski process may be doped with n-type impurities by, e.g., an ion implantation process. Also, the base substrate may be doped with carbon or nitrogen by, e.g., an ion implantation process, so that the lower substrate 10 having the oxygen precipitates 12 may be formed. The carbon or nitrogen may be uniformly doped from the upper portion of the lower substrate 10 at the distance of about 0.1 μm to about 5 μm from the top surface of the lower substrate 10 to the bottom of the lower substrate 10.

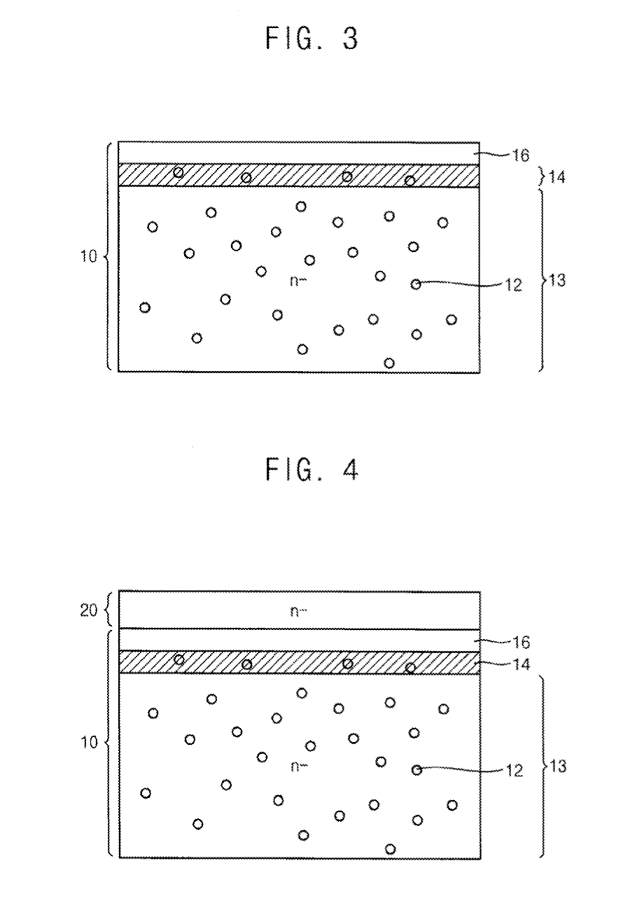

Due to the doping of carbon or nitrogen in the lower substrate 10, lattice defects or crystal defects such as dislocations of silicon crystal may be generated, so that the oxygen precipitates 12 may be formed at a vacancy generated by the lattice defects. The oxygen precipitates 12 may be uniformly formed from the upper portion of the lower substrate 10 at the distance of about 0.1 μm to about 5 μm from the top surface of the lower substrate 10 to the bottom of the lower substrate 10. By the oxygen precipitates 12, metallic contaminants may be collected or gettered in the bulk area 13 (refer to FIG. 3) of the lower substrate 10.

Referring to FIG. 3, the lower substrate 10 may be doped with p-type or n-type impurities by an ion implantation process to have a second impurity concentration, so that a metallic-contaminant collection area 14 may be formed in the lower substrate 10. Thus, the metallic-contaminant collection area 14 may be a p+ doping region or an n+ doping region. Also, the metallic-contaminant collection area 14 may have defects or damages due to the ion implantation process.

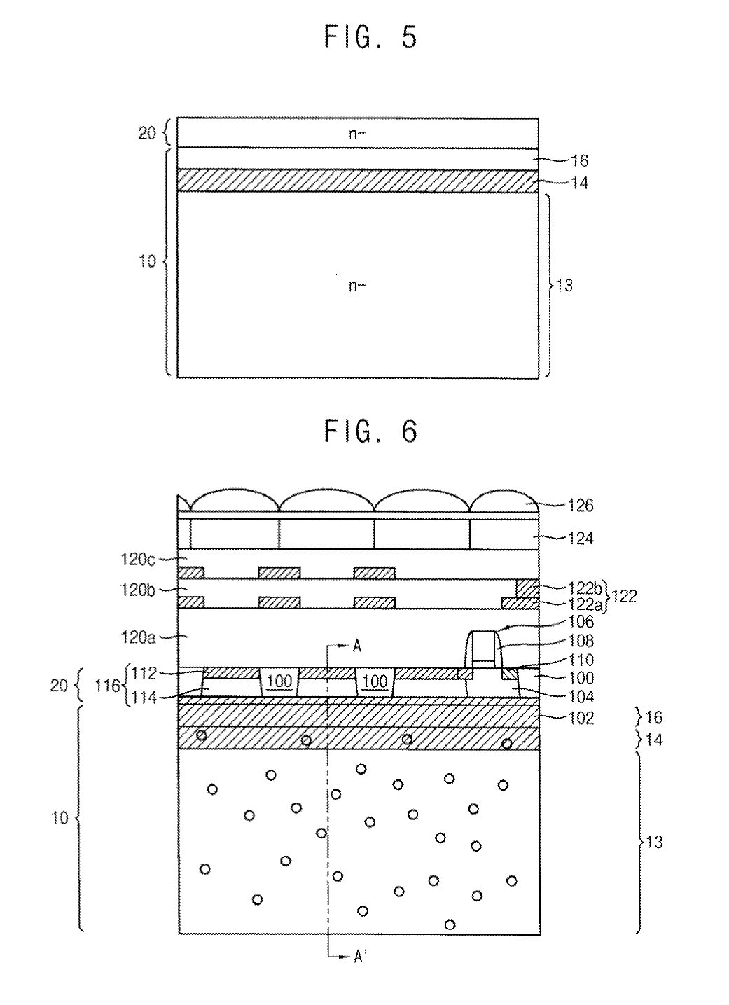

The ion implantation process may be performed with an energy of about 100 KeV to about 2000 KeV, and the second impurity concentration may be in a range of about 10E12 atoms/cm² to about 1E16 atoms/cm². When the ion implantation process is performed with an energy lower than about 100 KeV, sufficient defects or damages may not be generated in the metallic-contaminant collection area 14, and the defects or damages of the metallic-contaminant collection area 14 may be cured by a heat treatment subsequently performed. When ion implantation process is performed with an energy higher than about 2000 KeV, excessive defects or damages may be generated in the metallic-contaminant collection area 14 so that an epitaxial layer 20 (refer to FIG. 4) having no crystal defects may not be subsequently formed.

The ion implantation may be performed so that an upper surface of the metallic-contaminant collection area 14 may be in a range of about 0.1 μm to about 3 μm from the top surface of the lower substrate 10. Thus, the lower substrate 10 may include an upper area 16 on the metallic-contaminant collection area 14, and a thickness of the upper area 16 in the first direction may be in a range of about 0.1 μm to about 3 μm. The upper area 16 may have neither crystal defects nor oxygen precipitates, and may be doped with n-type impurities.

The metallic-contaminant collection area 14 may be spaced apart from the top surface of the lower substrate 10, so that the defects of the metallic-contaminant collection area 14 may not be transferred to the epitaxial layer 20. Thus, the epitaxial layer 20 having no crystal defects may be subsequently formed.

The ion implantation may be performed so that the metallic-contaminant collection area 14 may have a thickness in the first direction in a range of about 0.5 μm to about 5 μm.

The metallic-contaminant collection area 14 may be doped with p-type impurities, e.g., boron, indium, gallium, etc., or n-type impurities, e.g., arsenic, phosphorus, antimony, etc.

A polarity of the impurities doped into the metallic-contaminant collection area 14 may be opposite to that of metallic contaminants that may be collected or gettered by the metallic-contaminant collection area 14. Most of the metallic contaminants found in the semiconductor device may have a positive charge, and thus the metallic-contaminant collection area 14 may be doped with the p-type impurities to have a negative charge or a negative ion. In example embodiments, the ion implantation process may be performed to dope boron into the metallic-contaminant collection area 14 with an energy of about 100 KeV to about 2000 KeV, so that metallic-contaminant collection area 14 may be doped with boron having an impurity concentration of about 10E12 atoms/cm² to about 1E16 atoms/cm².

Referring to FIG. 4, the epitaxial layer 20 may be formed on the lower substrate 10 by an epitaxial growth. The epitaxial growth may be performed from the top surface of the lower substrate 10 having no crystal defects, so that the epitaxial layer 20 may have no crystal defects. Thus, the semiconductor device formed on the epitaxial layer 20 may have high performance and reliability.

The epitaxial layer 20 may be doped with n-type impurities or p-type impurities to have a third impurity concentration. The third impurity concentration may be lower than the second concentration. Hereinafter, the epitaxial layer 20 lightly doped with n-type impurities will be illustrated, for the convenience of explanation. Thus, the epitaxial layer 20 may be a n− single crystalline silicon layer. In example embodiments, the doping process may be performed while the epitaxial layer 20 is formed. In another implementation, the doping process may be performed after forming the epitaxial layer 20.

As described above, the substrate structure for fabrication of a semiconductor device of FIG. 1 may be formed. The substrate structure may include the metallic-contaminant collection area 14 in which metallic contaminants may be collected or gettered by a relaxation gettering due to the defects or damages thereof and a segregation gettering due to an electrical force of attraction. Also, the oxygen precipitates 12 may be formed in the bulk area 13 of the lower substrate 10. Thus, the metallic contaminants may be effectively collected or gettered in the lower substrate, and thus the epitaxial layer 20 may have reduced metallic contaminants.

FIG. 5 is a cross-sectional view illustrating a substrate structure for fabrication of a semiconductor device in accordance with example embodiments.

The substrate structure of FIG. 5 may not be doped with carbon or nitrogen, and the substrate structure may be substantially the same as that of FIG. 1, except that the substrate structure may include a very small amount of oxygen precipitate.

Referring to FIG. 5, the substrate structure for fabrication of a semiconductor device may include a lower substrate 10 that may include single crystalline silicon doped with n-type impurities having a first impurity concentration. An epitaxial layer 20 may be formed on the lower substrate 10. The epitaxial layer 20 may serve as a region for forming the semiconductor device, and may be doped with n-type impurities or p-type impurities to have a third impurity concentration. In example embodiments, the first and third impurity concentrations may be equal to or less than about 1E13 atoms/cm². Hereinafter, only the case in which the epitaxial layer 20 is lightly doped with n-type impurities will be illustrated.

A process to dope carbon or nitrogen into the lower substrate 10 may be omitted so that the lower substrate 10 is not processed to include oxygen precipitates. However, when the lower substrate 10 is formed by the Czochralski process, a very small amount of oxygen precipitates may be naturally generated in the lower substrate 10.

A metallic-contaminant collection area 14 may be formed in the lower substrate 10, and may be doped with n-type impurities or p-type impurities to have a second impurity concentration. The second impurity concentration may be higher than the first and third impurity concentrations. Thus, the metallic-contaminant collection area 14 may be a p+ doping region or an n+ doping region.

An upper surface of the metallic-contaminant collection area 14 may be disposed at a distance in a range of about 0.1 μm to about 3 μm from the top surface of the lower substrate 10. Also, the thickness of the metallic-contaminant collection area 14 in the first direction may be in a range of about 0.5 μm to about 5 μm. The second concentration of the metallic-contaminant collection area 14 may be in a range of about 1E12 atoms/cm² to about 1E16 atoms/cm². The lower substrate 10 may include an upper area 16 on the metallic-contaminant collection area 14. The upper area 16 may have neither crystal defects nor oxygen precipitates, and may be doped with n-type impurities.

Metallic contaminants in a region for forming the semiconductor device may be effectively collected or gettered in the metallic-contaminant collection area 14 by a relaxation gettering due to the defects or damages therein and a segregation gettering due to the electrical force of attraction. Thus, the metallic contaminants of the epitaxial layer 20 may decrease.

The substrate structure of FIG. 5 may be formed by processes substantially the same as those illustrated with reference to FIGS. 2 to 4. However, carbon or nitrogen may not be doped into the lower substrate 10. Thus, the lower substrate 10 including a single crystalline silicon and doped with n-type impurities may be formed, and then processes substantially the same as those illustrated with reference to FIGS. 3 and 4 may be performed to form the substrate structure of FIG. 5.

Various semiconductor devices may be formed on the substrate structure in accordance with example embodiments. Hereinafter, a CMOS image sensor formed on the substrate structure may be illustrated.

FIG. 6 is a cross-sectional view illustrating a CMOS image sensor on a substrate structure in accordance with example embodiments.

Referring to FIG. 6, the substrate structure may include an n− lower substrate 10 and epitaxial layer 20 stacked on the n− lower substrate 10, and the lower substrate 10 may include a metallic-contaminant collection area 14, as shown in FIG. 1. In example embodiments, the epitaxial layer 20 may be lightly doped with n-type impurities. In another implementation, the epitaxial layer 20 may be lightly doped with p-type impurities. Hereinafter, only the n− epitaxial layer 20 will be illustrated, for the convenience of explanation.

An upper portion of the n− epitaxial layer 20 may serve as an active region for forming the CMOS image sensor, and thus unit cells of the CMOS image sensor may be formed on the epitaxial layer 20.

The epitaxial layer 20 may include the active region for forming the CMOS image sensor and a field region on which an isolation layer pattern 100 may be formed to be electrically insulated from the CMOS image sensor. The epitaxial layer 20 may include a trench (not shown) in which the isolation layer pattern 100 may be formed.

A first p-type region 112 doped with p-type impurities may be formed at an upper portion of the epitaxial layer 20. A lower portion of the epitaxial layer 20 under the first p-type region 112 may include n-type impurities that has been initially doped into the epitaxial layer 20, and may be referred to as a first n-type region 114. A thickness of the first p-type region 112 may be smaller than that of the first n-type region 114. The first p-type region 112 may improve light sensitivity and prevent charge loss due to damages of a surface of the epitaxial layer 20.

A second p-type region 102 may be formed beneath the first n-type region 114. A lower surface of second p-type region 102 may contact an upper surface of the metallic-contaminant collection area 14 of the lower substrate 10. A bulk area 13 under the metallic-contaminant collection area 14 may be lightly doped with n-type impurities.

In a cross-sectional view of a photodiode region from a top toward a bottom of the substrate structure in the first direction, the photodiode region may include the first p-type region 112, the first n-type region 114, the second p-type region 102, the metallic-contaminant collection area 14, and the n− bulk area 13. Thus, the photodiode region may have a junction structure of p-type impurities, n-type impurities, p-type impurities and n-type impurities, regardless of the conductivity type of the metallic-contaminant collection area 14.

When the metallic-contaminant collection area 14 includes p-type impurities, the second p-type region 102 and the metallic-contaminant collection area 14 may serve as a p-type impurity region. Thus, a thickness in the first direction of the p-type impurity region between n-type impurity regions may increase. In another implementation, the second p-type region 102 may not be formed, i.e., the second p-type region 102 may be replaced by the metallic-contaminant collection area 14.

In another implementation, when the metallic-contaminant collection area 14 includes n-type impurities, the metallic-contaminant collection area 14 and the bulk area 13 may serve as an n-type impurity region. Thus, a thickness in the first direction of the n-type impurity region may increase.

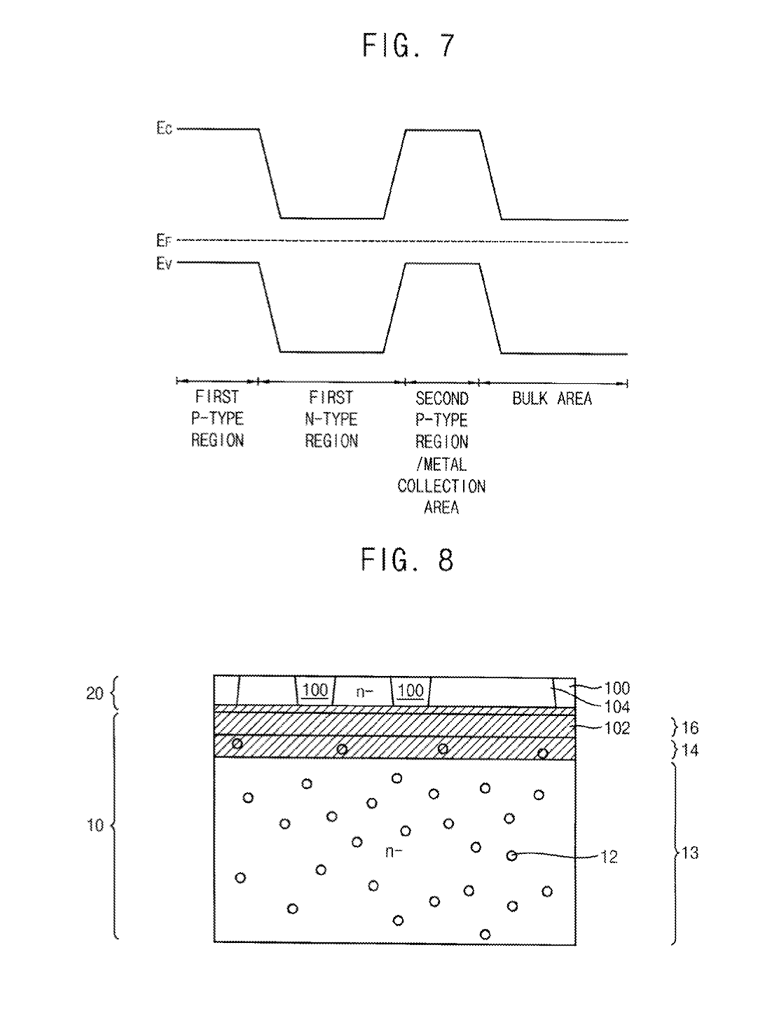

FIG. 7 is an energy band diagram of a portion of the substrate structure cut along a line A-A′ of FIG. 6.

FIG. 7 may be an energy band diagram of the photodiode region from the top toward the bottom of the substrate structure in the first direction.

When the metallic-contaminant collection area 14 is doped with p-type impurities, the energy band diagram may be shown as FIG. 7.

Referring to FIGS. 6 and 7, the second p-type region 102 and/or the metallic-contaminant collection area 14 doped with p-type impurities may be formed between the first n-type region 114 and the bulk area 13. A charge generated by irradiation of light may be collected in the first n-type region 114. The second p-type region 102 may form an energy barrier between the first n-type region 114 and the bulk area 13. Thus, a charge of the bulk area 13 may not easily move to the first n-type region 114. Therefore, a failure due to a charge leakage from the bulk area 13 to the first n-type region 114, such as a white spot, may decrease.

As described above, the CMOS image sensor may be formed on the substrate structure having the bulk area 13 doped with n-type impurities so that the CMOS image sensor may have a high performance.

Referring to FIG. 6 again, a p-well region 104 may be formed at a transistor region in the active region. A transistor including a gate structure may be formed on the p-well region 104. Spacers may be formed at sidewalls of the gate structure. The transistor may include a transfer transistor, a reset transistor, a drive transistor, a switching transistor, etc. As shown in FIG. 6, a floating diffusion region 110 highly doped with n-type impurities may be formed adjacent to the transfer transistor.

Insulating interlayers 120a, 120b and 120c may be formed on the epitaxial layer 20. A wiring structure 122 may be formed in the insulating interlayers 120a, 120b and 120c. The wiring structure 122 may include a contact and a line pattern. The wiring structure 122 may include a metal having a low resistance and/or a metal nitride, e.g., titanium, titanium nitride, tantalum, tantalum nitride, aluminum, copper, tungsten, etc. These may be used alone or in a combination thereof.

A color filter 124 and a micro lens 126 may be formed on a top surface of an uppermost one of the insulating interlayers 120a, 120b and 120c.

If metallic contaminants are included in the epitaxial layer 20 on which the CMOS image sensor may be formed, a charge may be generated even though a light may not be irradiated, and thus a distortion of an image may occur as if a light has been irradiated. A failure of the CMOS image sensor may occur even with a very small amount of metallic contaminant in the epitaxial layer 20. However, in the substrate structure in accordance with example embodiments, metallic contaminants may be effectively collected or gettered in the lower substrate 10 on which no semiconductor device may be directly formed. Thus, the epitaxial layer 30 for forming the semiconductor device may have no metallic contaminants, and the distortion of an image may decrease.

Additionally, in the CMOS image sensor formed on the substrate structure, the failure due to a charge leakage from the bulk area 13 to the first n-type region 114 such as a white spot may decrease. Thus, the CMOS image sensor formed on the substrate structure may have a high performance.

FIGS. 8 to 13 are cross-sectional views illustrating stages of a method of forming the CMOS image sensor of FIG. 6.

Referring to FIG. 8, a substrate structure for fabrication of semiconductor a device may be formed to include an n− lower substrate 10 and an epitaxial layer 20 on the n− lower substrate 10, and the lower substrate 10 may include a metallic-contaminant collection area 14, as shown in FIG. 1. Hereinafter, only the case in which the epitaxial layer 20 is lightly doped with n-type impurities will be illustrated. However, it will be understood that the epitaxial layer 20 may be a p− substrate lightly doped with p-type impurities. The substrate structure may be formed by processes substantially the same as those illustrated with reference to FIGS. 2 to 4.

P-type impurities may be doped into a lower portion of the epitaxial layer 20 to form a second p-type region 102. An upper surface of the second p-type region 102 may be formed to contact a lower surface of a photodiode subsequently formed. In example embodiments, the second p-type region 102 may be formed not only at the lower portion of the epitaxial layer 10 but also at an upper portion of the lower substrate 10 adjacent to an upper surface of a metallic-contaminant collection area 14. In another implementation, the second p-type region 102 may be only formed at the lower portion of the epitaxial layer 20.

When the metallic-contaminant collection area 14 includes p-type impurities, the second p-type region 102 may not be formed, i.e., the second p-type region 102 may be replaced by the metallic-contaminant collection area 14. In another implementation, even when the metallic-contaminant collection area 14 includes p-type impurities, the second p-type region 102 may be formed by a doping process.

A field region of the epitaxial layer 20 may be etched to form a trench (not shown). An isolation layer pattern 120 may be formed by filling the trench using an insulating material.

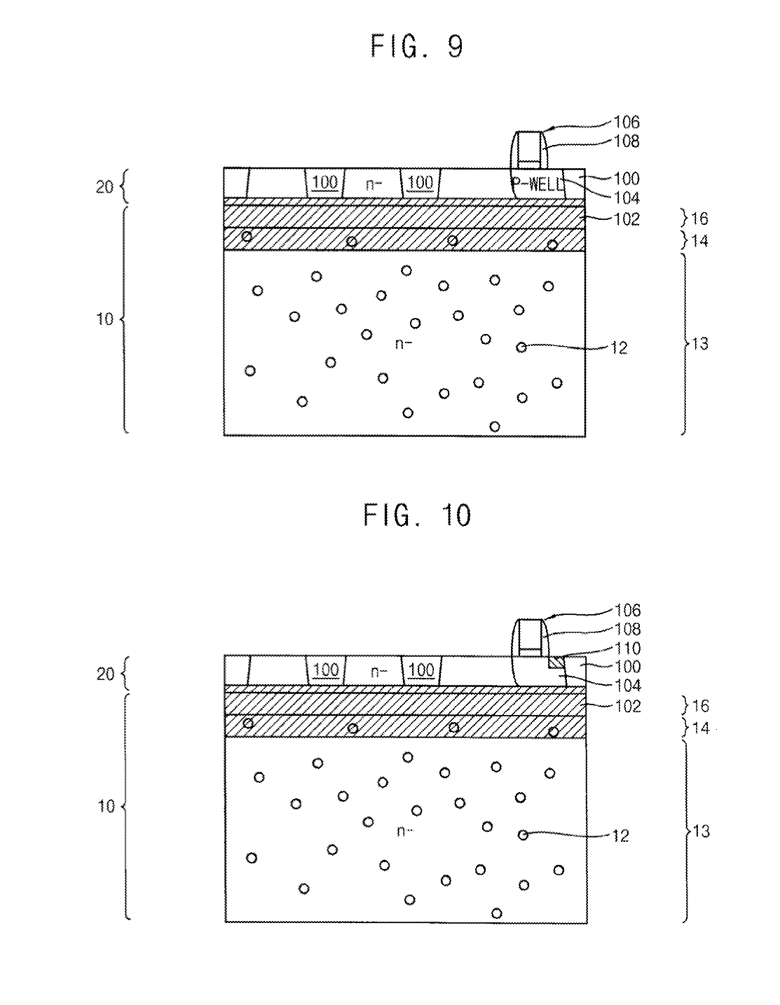

Referring to FIG. 9, a region for forming a transistor of the epitaxial layer 20 may be doped with p-type impurities by an ion implantation process using a first mask (not shown) to form a p-well region 104, and then the first mask may be removed.

A gate structure 106 may be formed on the epitaxial layer 20 by sequentially forming a gate insulation layer and a gate electrode layer, and patterning the gate electrode layer and the gate insulation layer. Spacers 108 may be formed on sidewalls of the gate structure 106.

The gate structure 106 may serve as a gate electrode of transistors in the CMOS image sensor, e.g., a transfer transistor, a reset transistor, a drive transistor, a switching transistor, etc. In example embodiments, the gate structure 106 of FIG. 9 may be a gate electrode of the transfer transistor.

Referring to FIG. 10, a portion of the epitaxial layer 20 adjacent to the gate structure 106 may be highly doped with n-type impurities by an ion implantation process using a second mask (not shown) to form a floating diffusion region 110, and then the second mask may be removed. During the ion implantation process, impurity regions (not shown) of the other transistors may be also formed.

Referring to FIG. 11, an upper portion of the epitaxial layer 20 may be highly doped with p-type impurities by an ion implantation process using a third mask (not shown) to form a first p-type region 112. A lower portion of the epitaxial layer 20 under the first p-type region 112 may include n-type impurities that has been initially doped into the epitaxial layer 20, and may be referred to as a first n-type region 114. A thickness of the first p-type region 112 may be smaller than that of the first n-type region 114. Thus, a photodiode 116 including the first n-type region 114 and the first p-type region 112 may be formed.

The first n-type region 114 in which a charge may be actually collected may include n-type impurities that have been initially doped into the epitaxial layer 20, and thus may be formed without performing an ion implantation process. In another implementation, the epitaxial layer 20 may be further doped with n-type impurities to form the first n-type region 114. When the epitaxial layer 20 is formed to be lightly doped with n-type impurities, the photodiode 116 may be easily formed.

Orders of the ion implantation process for forming the photodiode 116 and the transistors may have various modifications.

In a cross-sectional view of the photodiode region from a top toward a bottom of the substrate structure in the first direction, the photodiode region may include the first p-type region 112, the first n-type region 114, the second p-type region 102, the metallic-contaminant collection area 14, and the n− bulk area 13. Thus, the photodiode region may have a junction structure of p-type impurities, n-type impurities, p-type impurities and n-type impurities, regardless of the conductivity type of the metallic-contaminant collection area 14. Thus, the second p-type region 102 may form an energy barrier between the first n-type region 114 and the bulk area 13, and a failure due to a charge leakage from the bulk area 13 to the first n-type region 114, such as a white spot, may decrease.

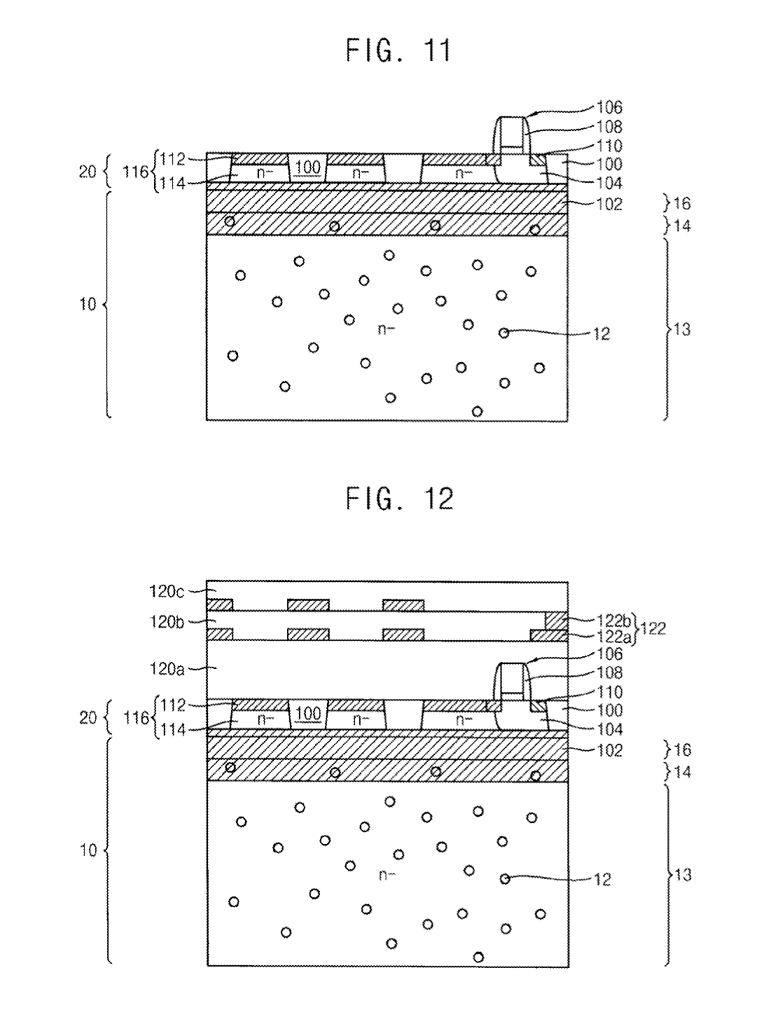

Referring to FIG. 12, insulating interlayers 120a, 120b and 120c may be sequentially formed on the epitaxial layer 20. A wiring structure 122 including a contact plug 122b and a line pattern 122a may be formed in the insulating interlayers 120a, 120b and 120c. The wiring structure 122 may be formed to include a metal having a low resistance and/or a metal nitride. The wiring structure 122 may be formed to include, e.g., titanium, titanium nitride, tantalum, tantalum nitride, aluminum, copper, tungsten, etc. These may be used alone or in a combination thereof.

Processes for forming the insulating interlayers 120a, 120b and 120c and the wiring structure 122 may be repeatedly performed. When the wiring structure 122 is formed, metallic contaminants may be generated in the insulating interlayers 120a, 120b and 120c, and the metallic contaminants may be diffused to the epitaxial layer 20. In example embodiments, the metallic contaminants may be collected or gettered at the metallic-contaminant collection area 14 and a portion of the bulk area 13 at which the oxygen precipitates 12 are formed under the epitaxial layer 20. Thus, the epitaxial layer 20 may not be contaminated by the metallic contaminants. Also, failures of the CMOS image sensor due to the metallic contaminants may be decreased.

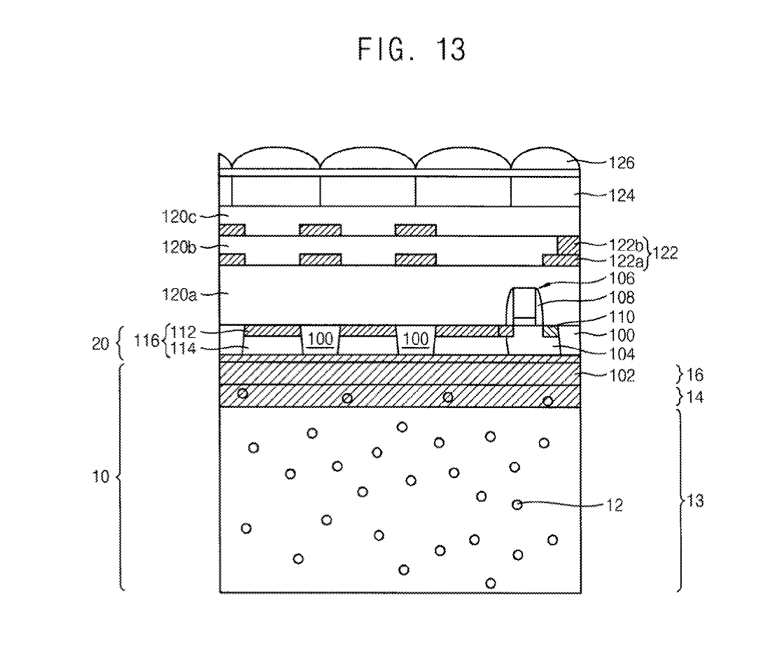

Referring to FIG. 13, a color filter 124 and a micro lens 126 may be sequentially formed on an uppermost one of the insulating interlayers 120a, 120b and 120c, and thus the CMOS image sensor may be formed.

As described above, the failure due to a charge leakage from the bulk area 13 to the first n-type region, such as a white spot, may decrease, and thus the CMOS image sensor having a high performance may be manufactured.

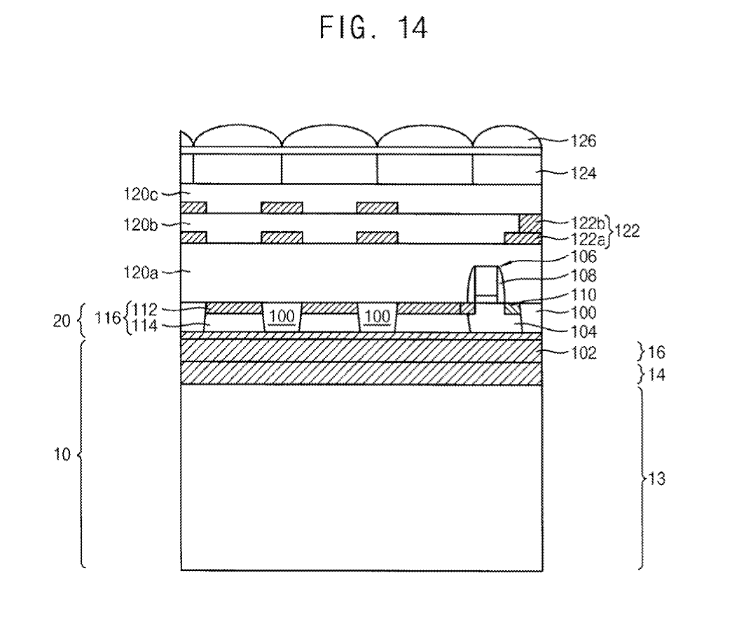

FIG. 14 is a cross-sectional view illustrating a CMOS image sensor in accordance with example embodiments.

The CMOS image sensor of FIG. 14 may be substantially the same as that of FIG. 6, except that the CMOS image sensor of FIG. 14 may be formed on the substrate structure for fabrication of a semiconductor device of FIG. 5. Thus, the lower substrate 10 of the substrate structure may not be doped with carbon or nitrogen so that the lower substrate 10 may include a very small amount of oxygen precipitates 12.

The CMOS image sensor of FIG. 14 may be formed on the substrate structure for fabrication of a semiconductor device of FIG. 5 by processes substantially the same as those illustrated with reference to FIGS. 8 to 13.

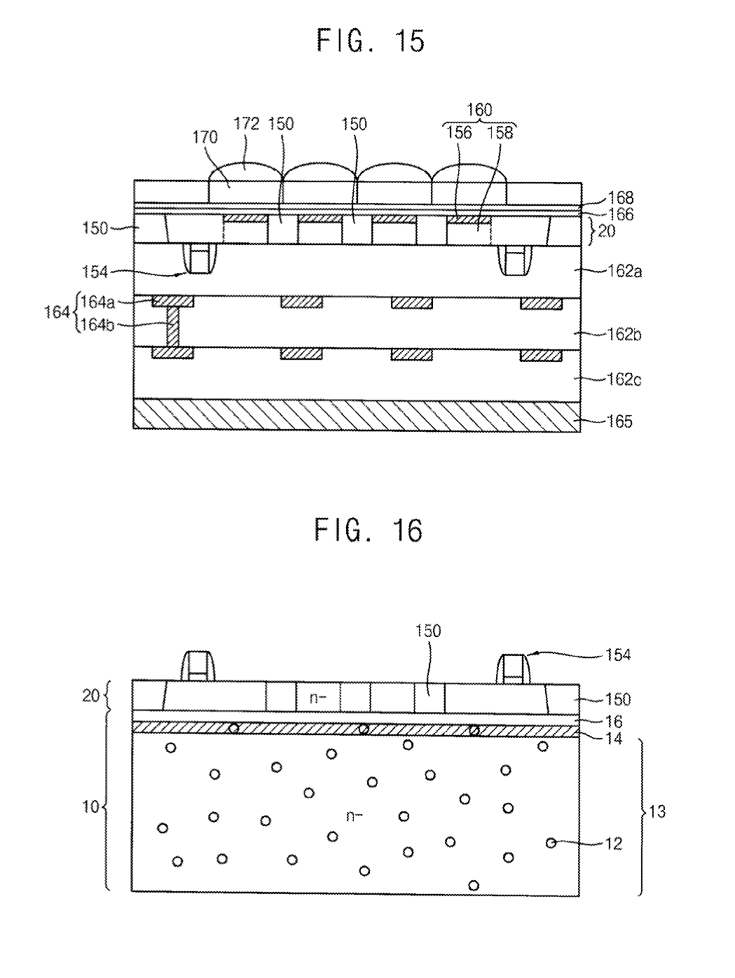

FIG. 15 is a cross-sectional view illustrating a CMOS image sensor in accordance with example embodiments. In example embodiments, the CMOS image sensor may be a backside illuminated (BSI) sensor.

Referring to FIG. 15, an epitaxial layer 20 may include a first surface on which unit devices may be formed and a second surface onto which a light may be illuminated. In example embodiments, the epitaxial layer 20 may be lightly doped with n-type impurities. In another implementation, the epitaxial layer 20 may be lightly doped with p-type impurities. Hereinafter, only the n− epitaxial layer 20 will be illustrated, for the convenience of explanation.

A portion of the epitaxial layer 20 adjacent to the first surface thereof may serve as an active region for forming the CMOS image sensor, and thus unit cells of the CMOS image sensor may be formed on the epitaxial layer 20.

The epitaxial layer 20 may include the active region for forming the CMOS image sensor and a field region on which an isolation layer pattern 150 may be formed to electrically insulate the CMOS image sensors from each other. The epitaxial layer 20 may include a trench (not shown) in which the isolation layer pattern 150 may be formed.

A transistor including a gate structure 154 may be formed on the first surface of the epitaxial layer 20. A unit pixel of the CMOS image sensor may include a transfer transistor, a reset transistor, a drive transistor, a switching transistor, etc., and the transistors may be formed on a pixel region of the epitaxial layer 20. A floating diffusion region (not shown) highly doped with n-type impurities may be formed in the epitaxial layer 20.

Insulating interlayers 162a, 162b and 162c may be sequentially formed on the first surface of the epitaxial layer 20. A wiring structure 164 may be formed in the insulating interlayers 162a, 162b and 162c. The wiring structure 164 may include a contact 164b and a line pattern 164a. The wiring structure 164 may include a metal having a low resistance and/or a metal nitride. The wiring structure may include, e.g., titanium, titanium nitride, tantalum, tantalum nitride, aluminum, copper, tungsten, etc. These may be used alone or in a combination thereof.

The wiring structure 164 may be formed on the first surface opposite to the second surface onto which a light may be illuminated. Thus, the wiring structure 164 may not affect efficiency and sensitivity of light so that the wiring structure 164 may be disposed without considering the position of a photodiode 160.

A support substrate 165 may be formed on a top surface of insulating interlayer 162c, which may be farthest among the insulating interlayers 162a, 162b and 162c from the first surface of the epitaxial layer 20.

The photodiode 160 may be formed in the epitaxial layer 20. An upper portion of the epitaxial layer 20, which may be adjacent to the second surface thereof, may serve as a first p-type region 156 doped with p-type impurities. A portion of the epitaxial layer 20 under the first p-type region 156 may include n-type impurities that have been initially doped into the epitaxial layer 20, and may be referred to as a first n-type region 158 A thickness of the first p-type region 156 may be smaller than that of the first n-type region 158.

An anti-reflection layer 166 and an insulating layer 168 may be formed on the second surface of the epitaxial layer 20. A plurality of color filters 170 may be formed on the insulating layer 168. Micro lenses 172 may be formed on the color filters 150, respectively. The micro lenses 172 may effectively guide an incident light to the photodiode 160 of the unit pixel.

As described above, a backside illuminated image sensor may be formed on the epitaxial layer 20, and thus a failure due to the metallic contaminants may decrease.

FIGS. 16 to 21 are cross-sectional views illustrating stages of a method of forming the substrate structure for fabrication of a semiconductor device of FIG. 15.

Referring to FIG. 16, the substrate structure may be formed to include an n− lower substrate 10 and an epitaxial layer 20 on the n− lower substrate 10, and the n− lower substrate 10 may include a metallic-contaminant collection area 14, as shown in FIG. 1. Hereinafter, only the case in which the epitaxial layer 20 is lightly doped with n-type impurities will be illustrated. However, in another implementation, the epitaxial layer 20 may be p− substrate lightly doped with p-type impurities. The substrate structure may be formed by processes substantially the same as those illustrated with reference to FIGS. 2 to 4.

The epitaxial layer 20 may have a thickness of about several micrometers to about tens of several micrometers. The epitaxial layer 20 may include a first surface and a second surface, which may be opposite to the first surface and contact the lower substrate 10.

An isolation layer pattern 150 may be formed at the first surface of the epitaxial layer 20, and thus a field region and an active region may be defined. For example, a portion of the epitaxial layer 20 may be etched to form a trench (not shown), and an insulating material may be filled into trench to form the isolation layer pattern 150. Unit cells of the image sensor may be electrically insulated from each other by the isolation layer pattern 150.

A gate structure 154 may be formed on the epitaxial layer 20 by sequentially forming a gate insulation layer and a gate electrode layer on the epitaxial layer 20, and patterning the gate insulation layer and the gate electrode layer. An impurity region may be formed at portions of the epitaxial layer 20 adjacent to the gate structure 154 so that a transistor may be formed on the epitaxial layer 20. A unit pixel of the CMOS image sensor may include a transfer transistor, a reset transistor, a drive transistor, a switching transistor, etc., and the transistors may be formed on a pixel region of the epitaxial layer 20. A floating diffusion region (not shown) highly doped with n-type impurities may be also formed in the epitaxial layer 20 while the impurity region may be formed.

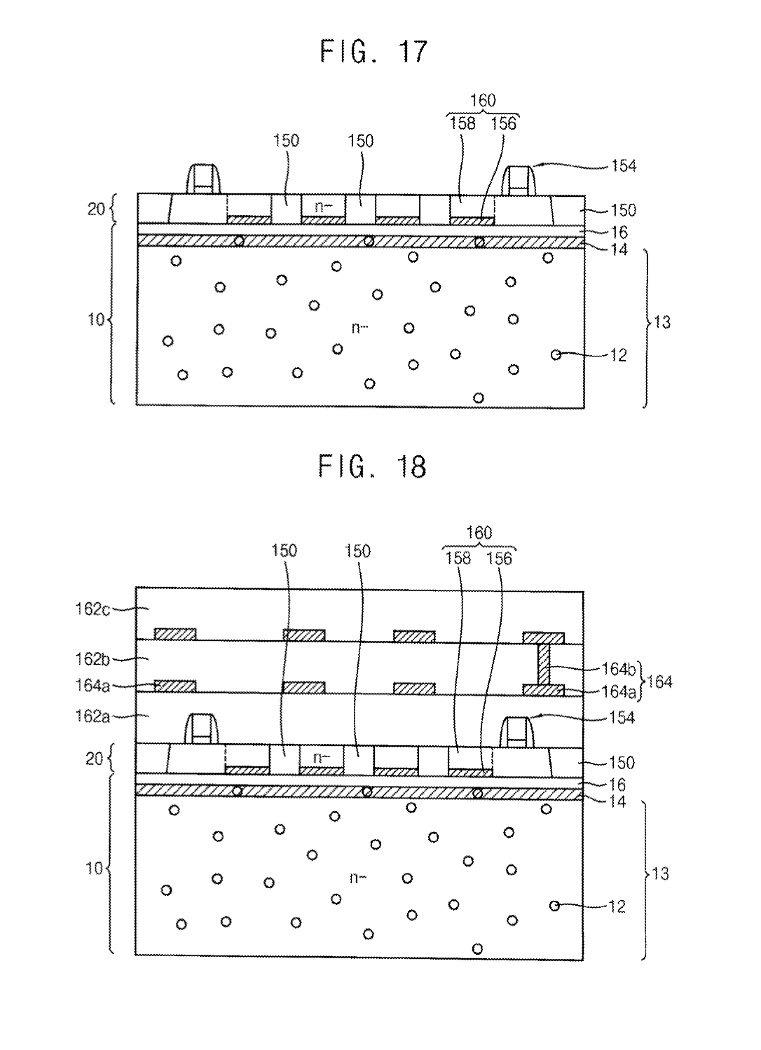

Referring to FIG. 17, a lower portion of the epitaxial layer 20 adjacent to the second surface thereof may be doped with p-type impurities by an ion implantation process using a first mask (not shown) to form a first p-well region 156. An upper portion of the epitaxial layer 20 on the first p-type region 156 may include n-type impurities that have been initially doped into the epitaxial layer 20, and may be referred to as a first n-type region 158. A thickness of the first p-type region 156 may be smaller than that of the first n-type region 158. Thus, a photodiode 160 including the first p-type region 156 and the first n-type region 158 may be formed in the epitaxial layer 20.

As described above, when the epitaxial layer 20 is initially doped with n-type impurities, the first n-type region 158 may be formed without performing an ion implantation process of n-type impurities. Thus, the photodiode 160 may be simply formed by doping p-type impurities only. In another implementation, the first n-type region 158 may be formed by performing an ion implantation process of n-type impurities.

Orders of the ion implantation process for forming the photodiode 160 and transistors may not be limited thereto, but may have various modifications.

Referring to FIG. 18, insulating interlayers 162a, 162b and 162c may be sequentially formed to cover the transistors on the first surface of the epitaxial layer 20. A wiring structure 164 including a contact plug 164b and a line pattern 164a may be formed in the insulating interlayers 162a, 162b and 162c. The wiring structure 164 may be formed to include a metal having a low resistance, e.g., titanium, titanium nitride, tantalum, tantalum nitride, aluminum, copper, tungsten, etc. These may be used alone or in a combination thereof. Processes for forming the insulating interlayers 162a, 162b and 162c and the wiring structure 164 may be repeatedly performed. While the wiring structure 164 is formed, metallic contaminants may be generated in the insulating interlayers 162a, 162b and 162c, and the metallic contaminants may be diffused to the epitaxial layer 20. However, in example embodiments, the metallic contaminants may be collected or gettered at the metallic-contaminant collection area 14 and a portion of the bulk area 13 at which the oxygen precipitates 12 are formed under the epitaxial layer 20. Thus, the epitaxial layer 20 may not be contaminated by the metallic contaminants.

The wiring structures 164 including the line pattern 164a and the contact plug 164b may have various types of structures and layer numbers according to the architecture of the device, without limitation. Also, the line pattern 164a and the contact plug 164b may not affect a transmission of light so that the line pattern 164a and the contact plug 164b may be disposed without considering the position of the photodiode 160.

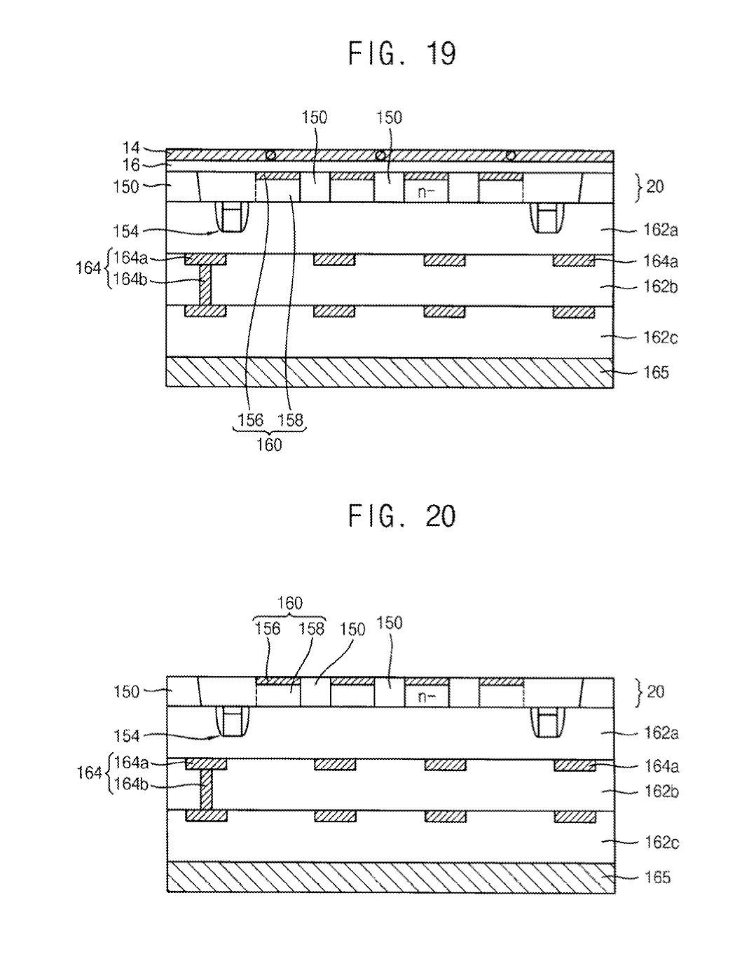

Referring FIG. 19, a support substrate 165 may be attached onto an uppermost one of the insulating interlayers 162a, 162b and 162c, and the resultant structure may be turned over. The support substrate 165 may support the epitaxial layer 20 and the lower substrate 10 during subsequent processes.

An upper portion of the lower substrate 10 may be removed, e.g., by grinding, cleaving, etc., so that the bulk area 13 of the lower substrate 10 is removed. In the grinding process, the metallic-contaminant collection area 14 may serve as a grinding stop layer. The metallic-contaminant collection area 14 may be highly doped with impurities to have a concentration higher than that of the bulk area 13, so that the metallic-contaminant collection area 14 and the bulk area 13 may have different grinding characteristics. Thus, the lower substrate 10 may be ground until the metallic-contaminant collection area 14 is exposed, and a process for forming an additional grinding stop layer may not be needed.

Referring FIG. 20, the metallic-contaminant collection area 14 and the upper area 16 may be removed by a grinding process and/or an etching process so that the second surface of the epitaxial layer 20 may be exposed. The metallic-contaminant collection area 14 and the upper area 16 may have thicknesses smaller than that of the bulk area 13, and may have impurity concentrations different from that of the bulk area 13. Thus, a grinding rate of the metallic-contaminant collection area 14 and the upper area 16 may be easily controlled.

The metallic-contaminant collection area 14 may include the metallic contaminants, and thus the metallic-contaminant collection area 14 may be removed.

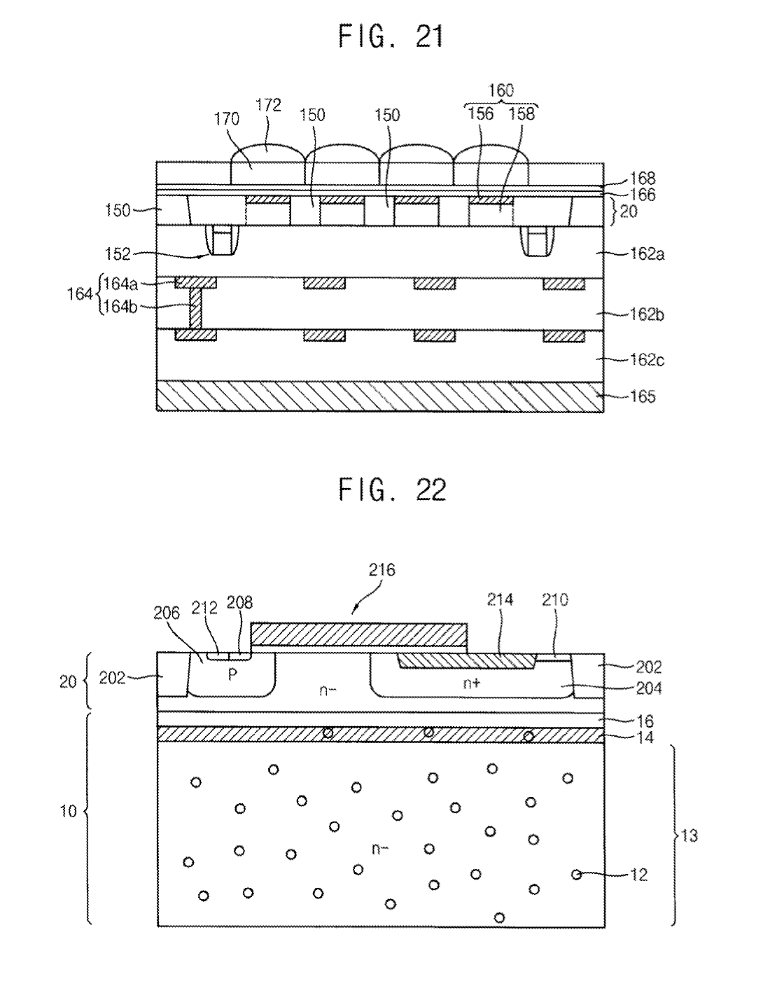

Referring FIG. 21, an anti-reflection layer 166 and an insulating layer 168 may be sequentially formed on the second surface of the epitaxial layer 20. The anti-reflection layer 166 may be formed to include a metal oxide having a high transmission of light. For example, the anti-reflection layer 166 may include, e.g., hafnium oxide, and the insulating layer 168 may include, e.g., silicon oxide, silicon nitride, etc.

A plurality of color filters 170 may be formed on the insulating layer 168. Micro lenses 170 may be formed on the color filters 170, respectively.

As illustrated above, the backside illuminated image sensor may be formed on the substrate structure for fabrication of a semiconductor device in accordance with example embodiments. Thus, the metallic contaminants of the epitaxial layer 20 may be decrease while the image sensor is formed. The metallic-contaminant collection area 14 of the substrate structure may serve as the grinding stop layer, so that the lower substrate 10 may be ground until a desired portion is exposed without forming a grinding stop layer. The image sensor may be formed on the epitaxial layer 20 of the substrate structure.

FIG. 22 is a cross-sectional view illustrating a power semiconductor device in accordance with example embodiments.

Referring to FIG. 22, the substrate structure for fabrication of a semiconductor device may include an n− lower substrate 10 and an epitaxial layer 20 on the n− lower substrate 10, and the n− lower substrate 10 may include a metallic-contaminant collection area 14, as shown in FIG. 1. Hereinafter, only the case in which the epitaxial layer 20 is lightly doped with n-type impurities will be illustrated. However, in another implementation, the epitaxial layer 20 may be a p− substrate lightly doped with p-type impurities. In example embodiments, the metallic-contaminant collection area 14 may be highly doped with p-type impurities, and may serve as a barrier region.

An upper portion of the epitaxial layer 20 may serve an active region for forming the semiconductor device. In example embodiments, unit cells of the power semiconductor device may be formed on the epitaxial layer 20, and each of the unit cells may include a power MOS transistor.

The epitaxial layer 20 may include an isolation layer pattern 202 defining an active region and a field region. The epitaxial layer 20 may include a first trench (not shown) in which the isolation layer pattern 202 may be formed.

A drift region 204 may be doped with n-type impurities in the epitaxial layer 20 to have a first impurity concentration. The first impurity concentration may be higher than that of n-type impurities of the epitaxial layer 20. Thus, the drift region 204 may be an n+ doping region.

A body region 206 doped with p-type impurities may be formed in the epitaxial layer 20. In example embodiments, the body region 206 may contact the drift region 204. In another implementation, the body region 206 may be spaced apart from the drift region 204.

A source region 208 and a body contact region 212 may be formed in the body region 206 adjacent to an upper surface of the epitaxial layer 20. The source region 208 may be doped with n-type impurities, and the body contact region 212 may be doped with p-type impurities.

A second trench (not shown) may be formed at the epitaxial layer 20 over the drift region 204, and an insulating layer pattern 214 may be formed in the second trench. The insulation layer pattern 214 may be formed over the drift region 204. A drain region 210 may be formed in the drift region 204 between the isolation layer pattern 202 and the insulating layer pattern 214. The drain region 210 may be doped with n-type impurities to have an impurity concentration higher than that of the drift region 204.

A gate structure 216 may be formed on the epitaxial layer 20 to partially cover the drift region 204, the insulating layer pattern 214 and the body region 206. Thus, the gate structure 216 may extend from an edge portion of the body region 206 to a portion of the insulating layer pattern 214.

As described above, the power semiconductor device may be formed on the n− epitaxial layer 20. Thus, in processes for forming the power semiconductor device, the doping processes for forming an n-type impurity region under the drift region 204 and the body region 206 may be omitted. The metallic-contaminant collection area 14 may serve as the barrier region, and thus the power semiconductor device may be simply manufactured.

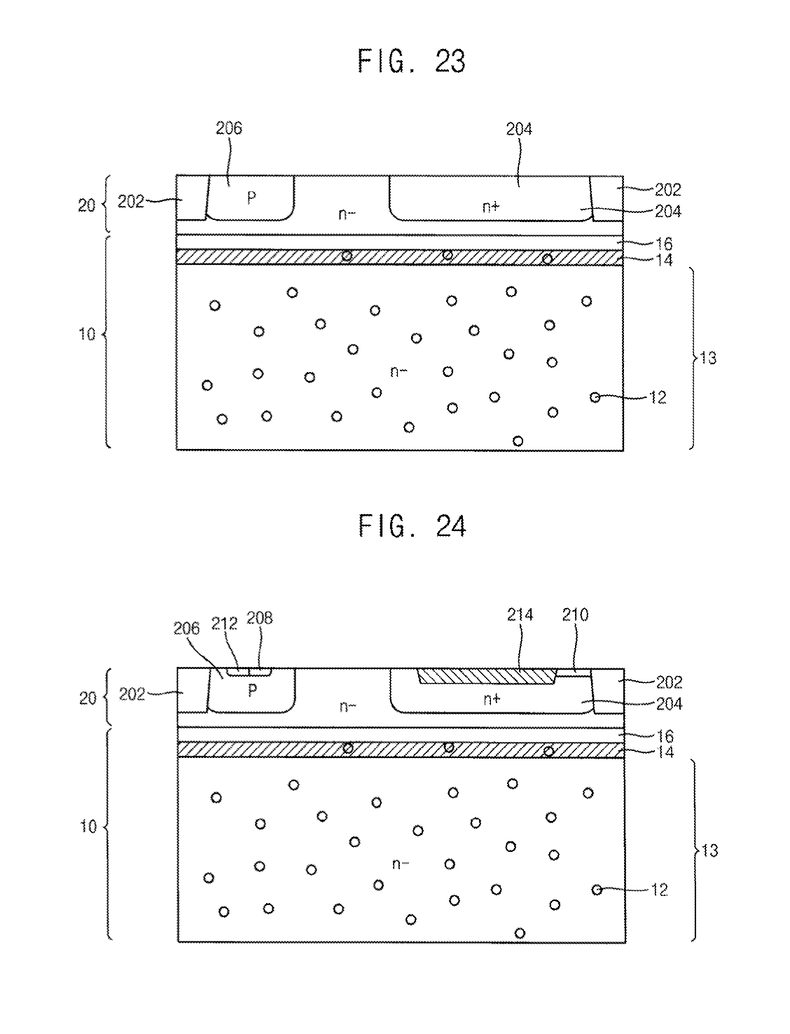

FIGS. 23 to 25 are cross-sectional views illustrating stages of a method of forming the power semiconductor device of FIG. 22.

Referring to FIG. 23, the substrate structure for fabrication of a semiconductor device may be formed to include an n− lower substrate 10 and an epitaxial layer 20 on the n− lower substrate 10, and the n− lower substrate 10 may include a metallic-contaminant collection area 14, as shown in FIG. 1. Hereinafter, only the case in which the epitaxial layer 20 is lightly doped with n-type impurities will be illustrated. However, in another implementation, the epitaxial layer 20 may be p− substrate lightly doped with p-type impurities. The substrate structure may be formed by processes substantially the same as those illustrated with reference to FIGS. 2 to 4.

The metallic-contaminant collection area 14 may serve as a barrier region, and thus a process for forming the barrier region may be omitted.

A portion of the epitaxial layer 20 may be etched to form a first trench (not shown), and an isolation layer pattern 120 may be formed by forming filling an insulating material into the first trench.

The epitaxial layer 20 may be doped with n-type impurities by an ion implantation process using a first mask (not shown) to form a drift region 204. The drift region 204 may be an n+ doping region. The epitaxial layer 20 may be doped with p-type impurities by an ion implantation process using a second mask (not shown) to form a body region 206. In example embodiments, the body region 206 may contact the drift region 204. In another implementation, the body region 206 may be spaced apart from the drift region 204.

The epitaxial layer 20 may be initially doped with n-type impurities, so that a doping process for forming an n− (n minus) impurity region under the drift region 204 and the body region 206 may be omitted. Thus, the processes for manufacturing the power semiconductor device may be simplified.

Referring to FIG. 24, an inner portion of body region 206 and an edge portion of the drift region 204 in the epitaxial layer 20 may be doped with n-type impurities to form a source region 208 and a drain region 210, respectively. Also, an inner portion of body region 206 in the epitaxial layer 20 may be doped with p-type impurities to form a body contact region 212.

A portion of the drift region 204 of the epitaxial layer 20 may be etched to form a second trench (not shown), and an insulating layer pattern 214 may be formed in the second trench.

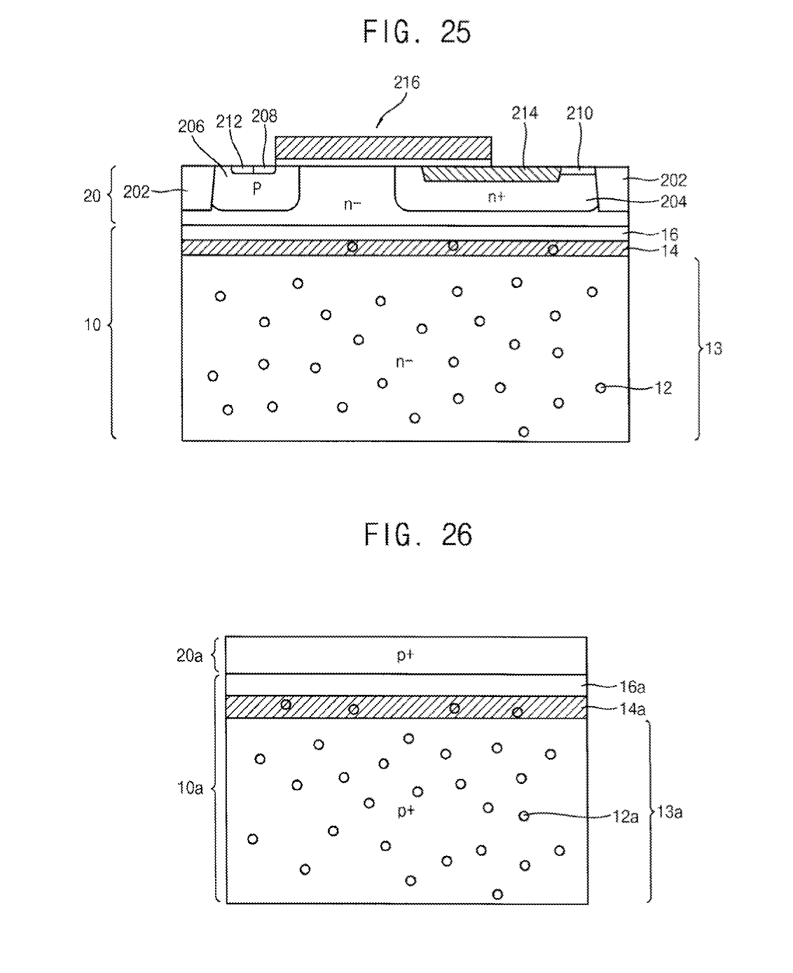

Referring to FIG. 25, a gate structure 216 may be formed on the epitaxial layer 20 by sequentially forming a gate insulation layer and a gate electrode layer, and patterning the gate electrode layer and the gate insulation layer. The gate structure 216 may extend from an edge of the body region 206 to a portion of the insulating layer pattern 214.

As described above, the power semiconductor devices of FIG. 22 may be manufactured.

FIG. 26 is a cross-sectional view illustrating a substrate structure for fabrication of a semiconductor device in accordance with example embodiments.

Referring to FIG. 26, the substrate structure may have a lower substrate 10a that may include a single crystalline silicon doped with p-type impurities. An epitaxial layer 20a may be formed on the lower substrate 10a. The epitaxial layer 20a may serve as a region for forming a semiconductor device.

The lower substrate 10a may be highly doped with p-type impurities to have a first impurity concentration, and thus the lower substrate 10a may be a p+ single crystalline silicon substrate. The p-type impurities may include, e.g., boron, indium, gallium, etc.

The lower substrate 10a may include oxygen precipitates 12a therein. When the lower substrate 10a is a p+ type substrate, the oxygen precipitates 12a may be formed in the lower substrate 10a without doping other ions, e.g., carbon or nitrogen. Thus, a size of a p-type impurity may be smaller than that of an n-type impurity. Thus, when the lower substrate 10a is highly doped with p-type impurities, the number of vacancy generated by doping the p-type impurities may increase and a large amount of oxygen precipitates 12a may be formed in the vacancy. When a p+ lower substrate 10a is formed by a Czochralski process, the oxygen precipitates 12 may be naturally generated in the lower substrate 10a.

A metallic-contaminant collection area 14a may be doped with n-type impurities or p-type impurities in the lower substrate 10a to have a second impurity concentration. The metallic-contaminant collection area 14a may have damages or defects due to an ion implantation process for doping impurities. Thus, the metallic-contaminant collection area 14a may be doped with impurities. The second impurity concentration may be higher than the first and third impurity concentrations. The metallic-contaminant collection area 14a may be a p++ doping region or an n++ doping region.

An upper surface of the metallic-contaminant collection area 14a may be disposed at a distance in a range of about 0.1 μm to about 3 μm from the top surface of the lower substrate 10a. A thickness of the metallic-contaminant collection area 14a in the first direction may be in a range of about 0.5 μm to about 5 μm. The second concentration of the metallic-contaminant collection area 14a may be in a range of about 1E12 atoms/cm² to about 1E16 atoms/cm². The metallic-contaminant collection area 14a may be doped with p-type impurities, e.g., boron, indium, gallium, etc., or n-type impurities, e.g., arsenic, phosphorus, antimony, etc.

The relaxation gettering due to damages or defects and the segregation gettering due to the electrical force of attraction may be generated together in the metallic-contaminant collection area 14a, so that the metallic contaminants of a region for forming the semiconductor device may be effectively collected or gettered in the metallic-contaminant collection area 14a. Thus, the metallic contaminants of the epitaxial layer 20a may decrease. The metallic-contaminant collection area 14a may be substantially the same as those illustrated with reference to FIG. 1.

The epitaxial layer 20a on the lower substrate 10a may have a proper thickness for forming the semiconductor device. The epitaxial layer 20a may be doped with p-type impurities to have a third impurity concentration. The third impurity concentration may be lower than the second impurity concentrations. The epitaxial layer 20a may be a p+ single crystalline silicon layer.

As described above, a relaxation gettering due to the defects and a segregation gettering due to the electrical force of attraction may be generated together in the metallic-contaminant collection area 14a so that the metallic contaminants of a region for forming the semiconductor device may be effectively collected or gettered in the metallic-contaminant collection area 14a.

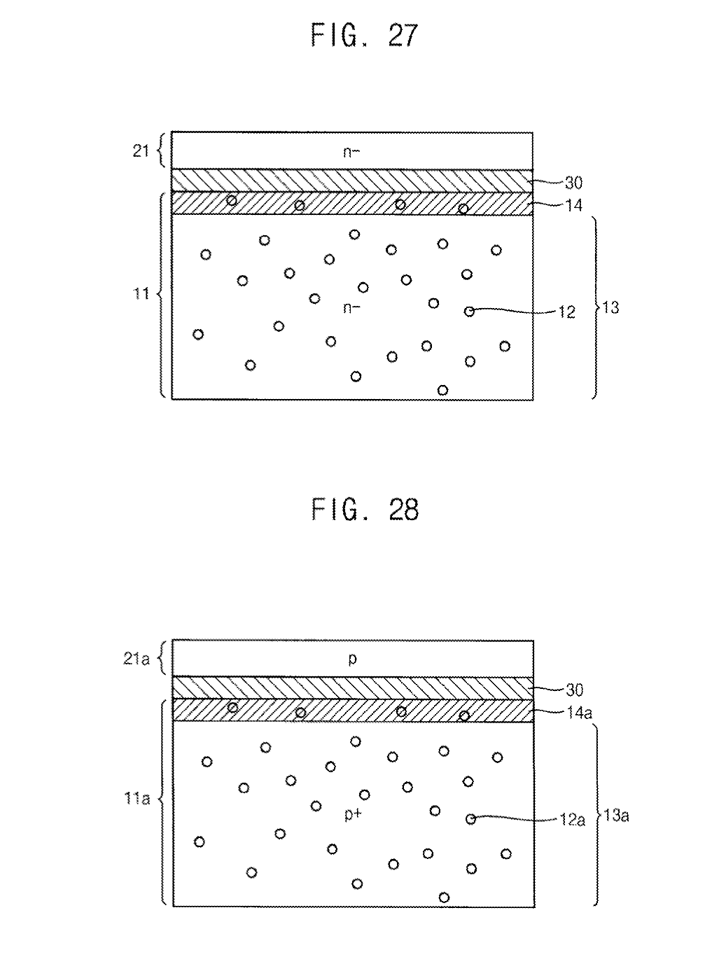

FIG. 27 is a cross-sectional view illustrating a substrate structure for fabrication of a semiconductor device in accordance with example embodiments.

Referring to FIG. 27, the substrate structure may have a lower substrate 11, a buried insulating layer 30 and a semiconductor layer 21 sequentially stacked. Thus, the substrate structure may be a silicon on insulator (SOI) substrate. The lower substrate 11 may include single crystalline silicon doped with n-type impurities. The semiconductor layer 21 may be doped with n-type impurities.

The lower substrate 11 may be an n− single crystalline silicon. The lower substrate 11 may be lightly doped with n-type impurities, and an entire region of the lower substrate 11 may have a first impurity concentration.

The lower substrate 11 may include oxygen precipitates 12 therein. The lower substrate 11 may be doped with carbon and/or nitrogen. The carbon or nitrogen may be doped to form the oxygen precipitates 12.

A metallic-contaminant collection area 14 may be doped with n-type impurities or p-type impurities in the lower substrate 11 to have a second impurity concentration. The metallic-contaminant collection area 14 may have damages or defects due to an ion implantation process for doping the impurities. Thus, the metallic-contaminant collection area 14 may be doped with impurities. The second impurity concentration may be higher than the first impurity concentration. The metallic-contaminant collection area 14 may be a p+ doping region or an n+ doping region.

An upper surface of the metallic-contaminant collection area 14 may be disposed at a distance in a range of about 0.1 μm to about 3 μm from the top surface of the lower substrate 11. In another implementation, the upper surface of the metallic-contaminant collection area 14 may be disposed at the top surface of the lower substrate 11. In the SOI substrate, the semiconductor layer 21 may not be formed by an epitaxial growth. Thus, even though the metallic-contaminant collection area 14 may be formed at a top portion of the lower substrate 11, lattice defects or crystal defects may not be generated in the semiconductor layer 21.

A thickness of the metallic-contaminant collection area 14 in the first direction may be in a range of about 0.5 μm to about 5 μm. The second concentration of the metallic-contaminant collection area 14 may be in a range of about 1E12 atoms/cm² to about 1E16 atoms/cm². The metallic-contaminant collection area 14 may be doped with p-type impurities, e.g., boron, indium, gallium, etc., or n-type impurities, e.g., arsenic, phosphorus, antimony, etc.

The semiconductor layer 21 may be doped with n-type impurities to have a third impurity concentration. The third impurity concentration may be lower than the second impurity concentrations.

As described above, a relaxation gettering due to the defects and a segregation gettering due to the electrical force of attraction may be generated together in the metallic-contaminant collection area 14 so that the metallic contaminants of a region for forming the semiconductor device may be effectively collected or gettered in the metallic-contaminant collection area 14.

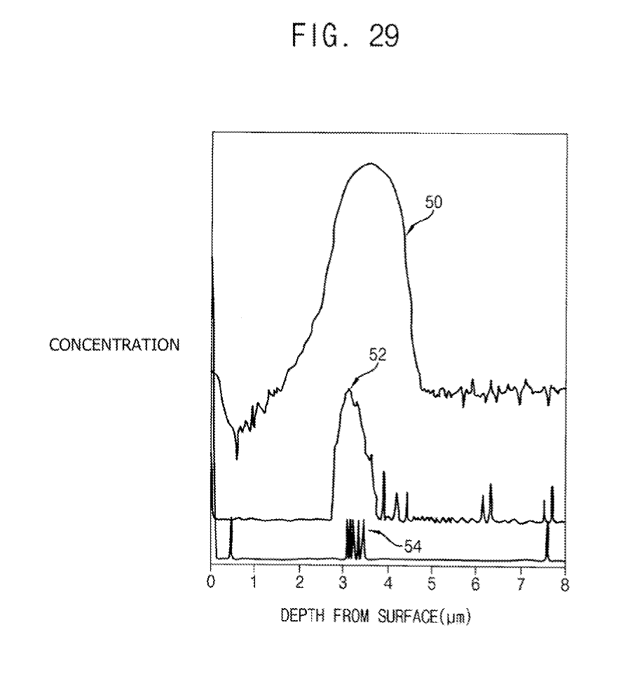

FIG. 28 is a cross-sectional view illustrating a substrate structure for fabrication of a semiconductor device in accordance with example embodiments.

Referring to FIG. 28, the substrate structure may have a lower substrate 11a, a buried insulating layer 30 and semiconductor layer 21a sequentially stacked. Thus, the substrate structure may be an SOI substrate. The lower substrate 11a may include single crystalline silicon doped with p-type impurities. The semiconductor layer 21a may be doped with p-type impurities.

The lower substrate 11a may be a p+ single crystalline silicon. The lower substrate 11a may be doped with p-type impurities to have a first impurity concentration.

The lower substrate 11a may include oxygen precipitates 12a therein.

A metallic-contaminant collection area 14a may be doped with n-type impurities or p-type impurities in the lower substrate 11a to have a second impurity concentration. The metallic-contaminant collection area 14a may have damages or defects due to an ion implantation process for doping of the impurities. The second impurity concentration may be higher than the first impurity concentration. The metallic-contaminant collection area 14a may be a p++ doping region or an n++ doping region.

An upper surface of the metallic-contaminant collection area 14a may be disposed at a distance in a range of about 0.1 μm to about 3 μm from the top surface of the lower substrate 11a. In another implementation, the upper surface of the metallic-contaminant collection area 14a may be disposed at the top surface of the lower substrate 11a.

The semiconductor layer 21a may be doped with p-type impurities to have a third impurity concentration. The third impurity concentration may be lower than the second impurity concentrations.

As described above, a relaxation gettering due to the defects and a segregation gettering due to the electrical force of attraction may be generated together in the metallic-contaminant collection area 14a so that the metallic contaminants of a region for forming the semiconductor device may be effectively collected or gettered in the metallic-contaminant collection area 14a.

### EXPERIMENT

### Example

First, a substrate structure of FIG. 1 was formed. For example, a thickness of the epitaxial layer was about 2 μm. The metallic-contaminant collection area was doped with boron ions.

The substrate structure was forcibly contaminated by contacting a solution including copper and a solution including tungsten.

Concentrations of boron, copper and tungsten from a top toward a bottom of the substrate structure was measured by a secondary ion mass spectroscopy (SIMS).

FIG. 29 is a graph illustrating the concentrations of boron, copper and tungsten in the substrate structure in accordance with Example, which were measured by the SIMS.

In FIG. 29, reference numerals “50,” “52” and “54” represent the concentrations of boron, copper and tungsten, respectively.

Referring to FIG. 29, a portion at which the concentration of the boron is high corresponds to the metallic-contaminant collection area. In the metallic-contaminant collection area, the concentrations of the copper and tungsten are high. Thus, metallic contaminants such as copper and tungsten were effectively collected or gettered in the metallic-contaminant collection area.

By way of summation and review, when a semiconductor device is manufactured on a silicon substrate, the silicon substrate may be contaminated by a metal. Due to metallic contaminants at a region for forming a semiconductor device in a silicon substrate, failures of the semiconductor device may be generated. For example, electric characteristics of an image sensor and/or a power device may be significantly changed by metallic contaminants in a silicon substrate.

As described above, embodiments relate to a substrate structure for fabrication of a semiconductor device and a semiconductor device on the substrate structure. In the substrate structure for fabrication of a semiconductor device, metallic contaminants may be effectively collected (gettered), so that a failure due to the metallic contaminants may be decreased. The substrate structure may be used for fabricating various types of semiconductor devices. For example, the substrate structure may be used for fabricating a semiconductor device that may be greatly affected by the metallic contaminants, such as an image sensor and/or a power device.

Example embodiments provide a substrate structure for fabrication of a semiconductor device having reduced metallic contaminants. Example embodiments also provide a semiconductor device on a substrate structure having reduced metallic contaminants. As described above, the substrate structure for fabrication of devices may have no or little metallic contaminants in a device forming region. A semiconductor device formed on the substrate structure for fabrication of devices may have a high performance without an effect of the metallic contaminants.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A substrate structure, comprising:
a lower substrate doped with n-type impurities having a first impurity concentration;
an epitaxial layer on the lower substrate; and
a metallic-contaminant collection area spaced apart from the epitaxial layer in the lower substrate, the metallic-contaminant collection area doped with impurities having a second impurity concentration higher than the first impurity concentration, the metallic-contaminant collection area having lattice defects, and an upper surface of the metallic-contaminant collection area being spaced apart from a top surface of the lower substrate at a distance in a range of about 0.1 μm to about 3 μm.

2. The substrate structure as claimed in claim 1, wherein the impurities doped into the metallic-contaminant collection area include n-type impurities or p-type impurities.

3. The substrate structure as claimed in claim 1, wherein a thickness of the metallic-contaminant collection area in a first direction substantially vertical to the top surface of the lower substrate is in a range of about 0.5 μm to about 5 μm.

4. The substrate structure as claimed in claim 1, wherein the second impurity concentration is in a range of about 1E12 atoms/cm² to 1E16 atoms/cm².

5. The substrate structure as claimed in claim 1, wherein the epitaxial layer is doped with n-type impurities having a third impurity concentration lower than the second impurity concentration.

6. The substrate structure as claimed in claim 1, wherein the lower substrate includes oxygen precipitates therein under the metallic-contaminant collection area.

7. The substrate structure as claimed in claim 1, wherein the lower substrate is doped with nitrogen or carbon under the metallic-contaminant collection area.

8. A semiconductor device, comprising:
a lower substrate doped with n-type impurities having a first impurity concentration;
an epitaxial layer on the lower substrate, the epitaxial layer doped with n-type impurities having a second impurity concentration;
a metallic-contaminant collection area spaced apart from the epitaxial layer in the lower substrate, the metallic-contaminant collection area doped with impurities having a second impurity concentration higher than the first and second impurity concentrations, the metallic-contaminant collection area having lattice defects, and an upper surface of the metallic-contaminant collection area being spaced apart from a top surface of the lower substrate at a distance in a range of about 0.1 μm to 3 μm; and
a unit cell formed on the epitaxial layer, a portion of the epitaxial layer serving as an active region for forming the unit cell.

9. The semiconductor device as claimed in claim 8, wherein the unit cell is a unit cell of an image sensor, and wherein the unit cell of the image sensor includes a photodiode in the epitaxial layer, the photodiode contacting the upper surface of the metallic-contaminant collection area.

10. The semiconductor device as claimed in claim 9, wherein the photodiode, the metallic-contaminant collection area and a portion of the lower substrate under the metallic-contaminant collection area have a junction structure of p-type impurities, n-type impurities, p-type impurities, and n-type impurities in a first direction substantially vertical to a top surface of the lower substrate.

11. The semiconductor device as claimed in claim 8, wherein the unit cell is a unit cell of a power semiconductor device, and the unit cell of the power semiconductor device includes a power MOS transistor.

12. The semiconductor device as claimed in claim 8, wherein the second impurity concentration is in a range of about 1E12 atoms/cm² to about 1E16 atoms/cm².

13. The semiconductor device as claimed in claim 8, wherein the impurities doped into the metallic-contaminant collection area include n-type impurities or p-type impurities.

14. The semiconductor device as claimed in claim 8, wherein a polarity of the impurities doped into the metallic-contaminant collection area is opposite to that of metallic contaminants collected from the epitaxial layer.

15. The semiconductor device as claimed in claim 8, wherein a thickness of the metallic-contaminant collection area in a first direction substantially vertical to a top surface of the lower substrate is in a range of about 0.5 μm to about 5 μm.

16. A semiconductor device, comprising:
a single crystalline body region doped with a first type impurity at a first concentration;
a first region, the first region being in the body region and doped with one or more of nitrogen or carbon;
a second region in the body region, the second region being doped with first type or second type impurities at a second concentration higher than the first concentration; and
an epitaxial region on the body region, the second region being spaced apart from the epitaxial region and below the epitaxial region such that the second region is covered by the epitaxial region but does not contact the epitaxial region.

17. The semiconductor device as claimed in claim 16, wherein the first type impurity is n-type, the second type impurity is p-type, and the second region is doped with the first type impurities.

18. The semiconductor device as claimed in claim 16, wherein the first type impurity is n-type, the second type impurity is p-type, and the second region is doped with the second type impurities.

19. The semiconductor device as claimed in claim 16, wherein the first type impurity is n-type, the second type impurity is p-type, and the epitaxial region is doped with the first type impurities at a third concentration that is lower than the second concentration.

20. The semiconductor device as claimed in claim 16, wherein the body region, the first region, the second region, and the epitaxial region are all laterally continuous and laterally coextensive, and an active region and one or more impurity wells are on the epitaxial region on an opposite side of the epitaxial region from the second region.
